(19) United States
(12) Patent Application Publication
(10) Pub. No.: US 2026/0238162 A1
(43) Pub. Date: Aug. 13, 2026

(54) A LOCAL OSCILLATOR (LO) DOUBLE EDGE-TUNING IQ IMBALANCE CALIBRATION TECHNIQUE FOR MODERN-DAY TRANSCEIVERS

(71) Applicant: KING FAHD UNIVERSITY OF PETROLEUM AND MINERALS, Dhahran (SA)

(72) Inventor: Hussam Abdullah H. ALSHAMMARY, Dhahran (SA)

(73) Assignee: KING FAHD UNIVERSITY OF PETROLEUM AND MINERALS, Dhahran (SA)

(21) Appl. No.: 19/053,270

(22) Filed: Feb. 13, 2025

(51) Int. Cl. H03D 3/00; H04B 1/10; H04B 1/16

(52) U.S. Cl. CPC H03D 3/009; H04B 1/10; H04B 1/1638

(57) ABSTRACT

A method and an apparatus for negating a hardware mismatch in a Radio Frequency (RF) front-end with an on-chip passive double edge-tuning mechanism includes generating a pair of Local Oscillator (LO) signals with a predefined 90° phase difference. The method includes adjusting a rising edge and a falling edge of one of the pair of LO signals, using a passive delay tuning mechanism, to compensate for a gain mismatch, ε, and a phase mismatch, θ, between the pair of LO signals. The method includes performing the adjusting directly in a RF domain at LO signal generation stage, prior to digitization by an Analog-to-Digital Converter (ADC) in a receiver front-end of the RF front-end, or after Digital-to-Analog Converter (DAC) in a transmitter front-end of the RF front-end.

### STATEMENT OF ACKNOWLEDGEMENT

Support provided by the Deanship of Scientific Research (DSR) at King Fahd University of Petroleum ε Minerals (KFUPM), Dhahran, Saudi Arabia is gratefully acknowledged.

### BACKGROUND

### Technical Field

The present disclosure is directed to Radio Frequency (RF) communication systems, and more particularly to a method and a system of negating a hardware mismatch in an RF front-end with an on-chip passive double edge-tuning mechanism.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Quadrature Amplitude Modulation (QAM) is a widely used technique in modern communication systems that maximizes spectrum utilization by combining In-phase (I) and Quadrature (Q) signals into discrete symbols. The constellation formed by these I and Q signals allows for high data throughput, making the QAM a key modulation scheme in high-performance communication systems. However, as communication systems evolve to support high-throughput applications, such as Wireless Local Area Network (WLAN) 802.11be, they are increasingly constrained by the limited allocated bandwidth and demanding Signal-to-Noise and Distortion Ratios (SNDRs). For instance, an SNDR greater than 40 decibel (dB) is required for a bandwidth of 320 megahertz (MHz) in WLAN 802.11be communication systems.

Achieving such stringent performance requirements, especially over wide bandwidths, requires minimizing noise and distortion in a Radio Frequency (RF) front-end of a communication system. However, despite efforts to improve RF and analog designs, gain and phase imbalances between the I and Q branches of a signal chain often led to a phenomenon known as residual sideband (RSB). The RSB arises when the I and Q imbalance produces unwanted spectral components, thus degrading the communication system's overall performance. This RSB sets a floor for an Error Vector Magnitude (EVM), which is a key measure of a signal quality, and limits an achievable SNDR.

For modern RF transceivers, a typical RSB resulting from a hardware mismatch between the I and Q channels is often in a range of −40 to −25 decibels for carrier (dBc). This hardware mismatch is particularly problematic for high-performance communication systems, where maintaining a high SNDR is crucial for minimizing errors in signal detection. In response to the above-listed challenges, conventional techniques have focused on the I and Q imbalance characterization and calibration techniques. The calibration techniques are generally implemented in either a digital domain or an analog domain. A digital domain calibration can offer high rejection of the I and Q imbalance, but it comes with a drawback of being power-hungry and requiring a large dynamic range in an Analog-to-Digital Converter (ADC). On the other hand, an analog domain calibration typically involves more power and area overhead. For instance, in some analog domain calibration techniques, the bias of a mixer is adjusted by adding extra switches in a signal path. However, such calibration techniques can result in significant increases in both power consumption and circuit area, thus making them impractical for power-efficient designs. The limitations of these existing calibration techniques, especially their impact on power consumption, circuit area, and complexity, highlight the need for a more efficient solution to mitigate the I and Q imbalance and its associated problems in the RF front-end designs.

Accordingly, it is one object of the present disclosure to provide a method and an apparatus for negating a hardware mismatch in the RF front-end with an on-chip passive double edge-tuning mechanism.

### SUMMARY

In an exemplary embodiment, a method of negating a hardware mismatch in a Radio Frequency (RF) front-end with an on-chip passive double edge-tuning mechanism is described. The method includes generating a pair of Local Oscillator (LO) signals with a predefined 90° phase difference. The method includes adjusting, using a passive delay tuning mechanism, a rising edge and a falling edge of one of the pair of LO signals to compensate for a gain mismatch, ε, between the pair of LO signals by symmetrically modifying a pulse width of a first LO signal of the pair of LO signals, and compensate for a phase mismatch, θ, between the pair of LO signals by symmetrically delaying or advancing both rising and falling edges of the first LO signal. The method includes performing the adjusting directly in a RF domain at LO signal generation stage, prior to digitization by an Analog-to-Digital Converter (ADC) in a receiver front-end of the RF front-end, or after Digital-to-Analog Converter (DAC) in a transmitter front-end of the RF front-end.

In another exemplary embodiment, an apparatus for negating a hardware mismatch in a Radio Frequency (RF) front-end is described. The apparatus includes an LO generator configured to generate a pair of LO signals with a predefined 90° phase difference. The apparatus includes a set of edge-tunable delay cells integrated within the LO generator, configured to passively modify a pulse width and a phase of the pair of LO signals to compensate for a gain mismatch, ε, or a phase mismatch, θ. The apparatus includes a controller configured to provide calibration codes to the set of edge-tunable delay cells for adjusting gain and phase imbalances based on the gain mismatch, ε, and the phase mismatch, θ.

In yet another exemplary embodiment, a non-transitory computer-readable medium having instructions stored therein that, when executed by one or more processors, cause the one or more processors to perform a method of negating a hardware mismatch in a Radio Frequency (RF) front-end with an on-chip passive double edge-tuning mechanism is described. The method includes generating a pair of Local Oscillator (LO) signals with a predefined 90° phase difference. The method includes adjusting, using a passive delay tuning mechanism, a rising edge and a falling edge of one of the pair of LO signals to compensate for a gain mismatch, ε, between the pair of LO signals by symmetrically modifying a pulse width of a first LO signal of the pair of LO signals, and compensate for a phase mismatch, θ, between the pair of LO signals by sym metrically delaying or advancing both rising and falling edges of the first LO signal. The method includes performing the adjusting directly in a RF domain at LO signal generation stage, prior to digitization by an Analog-to-Digital Converter (ADC) in a receiver front-end of the RF front-end, or after Digital-to-Analog Converter (DAC) in a transmitter front-end of the RF front-end.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A is a circuit diagram of a transmitter front-end with an In-phase (I) and Quadrature (Q) mismatch modeled as an absolute gain mismatch and an absolute phase mismatch, according to certain embodiments.

FIG. 1B is a circuit diagram of a receiver front-end with an I and Q mismatch modeled as an absolute gain mismatch and an absolute phase mismatch, according to certain embodiments.

FIG. 1C is a diagram representing an impact of the I and Q mismatch, according to certain embodiments.

FIG. 2 is a diagram depicting a graphical representation of an Error Vector Magnitude (EVM) versus an operation power curve with a residual side band (RSB), according to certain embodiments.

FIG. 3 is a diagram depicting a graphical representation of an RSB versus different gain mismatches and phase mismatches, according to certain embodiments.

FIG. 4A is a diagram representing an ideal condition of LOs with no mismatch, according to certain embodiments.

FIG. 4B is a diagram representing a condition with mismatched LOs for a gain calibration, according to certain embodiments.

FIG. 4C is another diagram representing a condition with mismatched LOs for gain and phase calibrations, according to certain embodiments.

FIG. 5 is a diagram representing a circuit with an on-chip passive double-edge tuning mechanism, according to certain embodiments.

FIG. 6A, is an exemplary diagram depicting an EVM floor for a raw I and Q imbalance for 64 Quadrature Amplitude Modification (QAM), according to certain embodiments.

FIG. 6B, is an exemplary diagram depicting an EVM floor for a calibrated I and Q imbalance for 64 QAM, according to certain embodiments.

FIG. 6C, is an exemplary diagram depicting an EVM floor for a raw I and Q imbalance for 16 QAM, according to certain embodiments.

FIG. 6D, is an exemplary diagram depicting an EVM floor for a calibrated I and Q imbalance for 16 QAM, according to certain embodiments.

FIG. 7 is a diagram depicting an inventor with an on-chip passive double-edge tuning mechanism, according to certain embodiments.

FIG. 8 is a diagram depicting a transient simulation for an ideal LO and mismatched LOs with different tuning codes, according to certain embodiments.

FIG. 9 is a diagram representing a graph depicting an EVM of a calibrated I and Q balance for a Quadrature Phase Shift Keying (QPSK) modulation versus temperature, according to certain embodiments.

FIG. 10 is a diagram of a method of negating a hardware mismatch in a Radio Frequency (RF) front-end with an on-chip passive double edge-tuning mechanism, according to certain embodiments.

FIG. 11 shows a computing environment according to exemplary embodiments.

FIG. 12 shows a schematic diagram of a data processing system, according to certain embodiments.

FIG. 13 shows an implementation of a processing unit with program instructions.

FIG. 14 shows an embodiment of an environment including distributed components such as a client and server machines.

### DETAILED DESCRIPTION

In the drawings, like reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values therebetween.

Aspects of this disclosure are directed to an apparatus and a method of negating a hardware mismatch in a Radio Frequency (RF) front-end with an on-chip passive double edge-tuning mechanism. To perform the negation of the hardware mismatch in the RF front-end, the method includes generating a pair of Local Oscillator (LO) signals with a predefined 90° phase difference. The method further includes adjusting, using a passive delay tuning mechanism, a rising edge and a falling edge of one of the pair of LO signals to compensate for a gain mismatch, ε, between the pair of LO signals by symmetrically modifying a pulse width, θ, of a first LO signal of the pair of LO signals, and compensate for a phase mismatch, θ, between the pair of LO signals by symmetrically delaying or advancing both rising and falling edges of the first LO signal. The method further includes performing the adjusting directly in a RF domain at LO signal generation stage, prior to digitization by an Analog-to-Digital Converter (ADC) in a receiver front-end of the RF front-end, or after Digital-to-Analog Converter (DAC) in a transmitter front-end of the RF front-end.

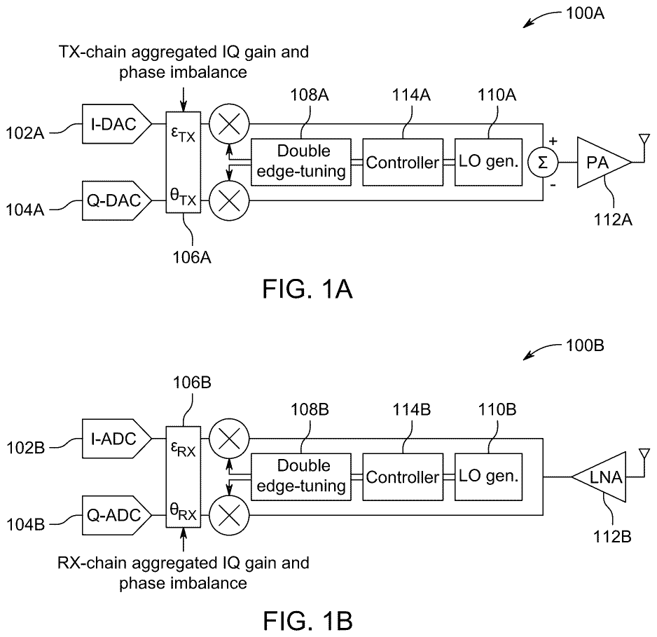

Referring now to FIG. 1A, the present disclosure provides a circuit diagram 100A representing a transmitter front-end with an In-phase (I) and Quadrature (Q) mismatch modeled as an absolute gain mismatch and an absolute phase mismatch, according to certain embodiments. In particular, the circuit diagram 100 represents the transmitter (Tx) front-end of a communication system at which the I and Q mismatch is modeled as the absolute gain mismatch (ε) and the absolute phase mismatch (θ). Examples of the communication system may include, but are not limited to, a wireless communication system, a Wireless-Fidelity (Wi-Fi), a satellite communication system, a radar system, a software-defined radio system, and a Bluetooth communication system. In an embodiment, the absolute gain mismatch (ε) occurs when the magnitudes (or amplitudes) of the I and Q components are not equal. For instance, both the I and Q components should have same amplitude for a balanced signal, but imperfections in the communication system can cause the signal of one component to be stronger than the other component. Further, the absolute phase mismatch (θ) refers to a situation where a phase difference between the I and Q components deviates from an ideal 90 degrees (i.e., a predefined 90° phase difference). The I and Q components should ideally be 90 degrees apart to maintain proper quadrature modulation, but phase errors can occur due to imperfections in the communication system. Examples of the imperfections of the communication system that may cause the absolute gain mismatch (ε), and the absolute phase mismatch (θ) include a signal path asymmetry, an imperfection in a RF calibration, imbalanced antennas, a power supply noise or ripple, temperature variations, and the like.

As depicted in FIG. 1A, the circuit diagram 100A includes an In-phase (I) Digital-to-Analog Convertor (DAC), represented as a I-DAC 102A, a Quadrature (Q) DAC, represented as a Q-DAC 104A, an LO generator 110A, and a power amplifier (PA) 112A. The I-DAC 102A is responsible for converting digital data (e.g., digital bits from a baseband signal) of the I component of the signal into an analog signal. This analog signal is then used in a modulation process for the communication system, where it is combined with the Q component to form a complex modulated signal. Further, the Q-DAC 104A is configured to convert the digital data of the Q component of the signal into the analog signal, complementing the I-component to form the complex modulated signal.

Further, a cumulative effect of the absolute gain mismatch (ε) and the absolute phase mismatch (θ) that arise from all components in a Tx signal chain is computed as depicted via 106A. Once the cumulative effect of the absolute gain mismatch (ε) and the absolute phase mismatch (θ) is computed, an on-chip passive double edge-tuning mechanism 108A is performed to compensate the absolute gain mismatch (ε) and the absolute phase mismatch (θ). The on-chip passive double edge-tuning mechanism 108A refers to adjusting the I and Q paths in such a way that both gain and phase imbalances (also referred to as gain and phase discrepancies) are corrected through passive means (like tuning resistors or capacitors, for example), ensuring that the I and Q components are balanced and accurately aligned. Once the gain and phase discrepancies based on the absolute gain mismatch (ε) and the absolute phase mismatch (θ) are corrected, the LO generator 110A is configured to generate a stable, high-frequency LO signal (or a pair of LO signals) by converting the signal associated with the I and Q components to a desired RF signal. In an embodiment, to convert the signal to the desired RF signal, the LO generator 110A may include a set of edge-tunable delay cells that are integrated within the LO generator. The set of edge-tunable delay cells is configured to passively modify a pulse width and a phase of the pair of LO signals to compensate for the absolute gain mismatch (ε) or the absolute phase mismatch (θ). For this controller (e.g., implemented as part of double edge-tuning mechanism 108A or 114A) is configured to provide calibration codes to the set of edge-tunable delay cells for adjusting gain and phase imbalances based on the absolute gain mismatch (ε) and the absolute phase mismatch (θ). Further, the PA 112A is configured to amplify the RF signal generated using the LO generator 110A, ensuring that the RF signal has sufficient power for transmission over long distances through an antenna. The PA 112A boosts the RF signal to a required power level while maintaining the RF signal integrity.

Referring now to FIG. 1B, the present disclosure provides a circuit diagram 100B of a receiver front-end with an I and Q mismatch modeled as an absolute gain mismatch and an absolute phase mismatch, according to certain embodiments. As depicted in FIG. 1A, the circuit diagram 100B includes an In-phase (I) Analog-to-Digital Convertor (ADC) represented as a I-ADC 102B, a Quadrature (Q) ADC, represented as a Q-ADC 104B, an LO generator 110B, and a Low Noise Amplifier (LNA) 112B. In an embodiment, the circuit diagram 100B may also include an antenna. The antenna is configured to receive an RF signal (e.g., RF signal transmitted by the transmitter of FIG. 1A). Further, the LNA 112B is configured to amplify the RF signal received from the antenna with minimal noise addition. The LNA 112B is configured to boost the weak RF signal strength before the weak RF signal is down-converted and digitized, ensuring the weak RF signal is strong enough for accurate conversion by the I-ADC 102B and the Q-ADC 104B. Further, the LO generator 110B is configured to generate the pair of LO signals that is mixed with the amplified RF signal received from the LNA 112B to down-convert the amplified RF signal to an Intermediate frequency (IF) or a baseband. Further, the on-chip passive double edge tuning mechanism 108B is used to address any gain and phase mismatches between the I and Q components of the down-converted RF signal. In other words, a controller 114B is used address any gain and phase mismatches between the I and Q components of the down-converted RF signal. In particular, the circuit diagram 100B represents the receiver (Rx) front-end of the communication system at which the I and Q mismatch is modeled as the absolute gain mismatch (ε) and the absolute phase mismatch (θ).

Further, a cumulative effect of the absolute gain mismatch (ε) and the absolute phase mismatch (θ) that arise from all components in a Rx signal chain is computed and reduced as depicted via 106B. Once the cumulative effect of the absolute gain mismatch (ε) and the absolute phase mismatch (θ) is reduced, a final RF signal is provided to the I-ADC 102B and the Q-ADC 104B. The I-ADC 102B is configured to convert the final RF signal (i.e., a received analog signal) representing the I component of the final RF signal into a digital format for further signal demodulation and decoding. The Q-ADC 104B is configured to convert the final RF signal representing the Q component of the final RF signal into a digital format for further signal demodulation and decoding.

Referring now to FIG. 1C, the present disclosure provides an exemplary diagram 100C representing an impact of an I and Q mismatch, according to certain embodiments. In particular, the exemplary diagram 100C represents the impact of the absolute gain mismatch (ε) and the absolute phase mismatch (θ) between the I and Q components, which results in the generation of a Receiver Signal Band (RSB), either from a transmitter (Tx) side or a receiver (Rx) side. This distortion in the signal caused by the absolute gain mismatch (ε) and the absolute phase mismatch (θ) can degrade a Signal-to-Noise Ratio (SNR) and often limits an Error Vector Magnitude (EVM) at an ADC input, adversely affecting an overall signal quality and performance of the communication system. The absolute gain mismatch (ε) and the absolute phase mismatch (θ) can lead to a creation of an image RSB, which can significantly affect a performance of the communication system. In FIG. 1C, a PA output 102C represents an output generated by the PA 112A of the Tx front-end of the communication system. The PA output 102C represents a raw output 102-2C and a calibrated output 102-4C generated by the PA 112A. In the raw output 102-2C and the calibrated out 104C, an x-axis represents a frequency at which the LO generator 110A operates (also referred to as an operation frequency (f_{LO})) to provide the pair of LO signals that needs to be mixed with the received signal. The raw output 102-2C represents a signal generated by the PA 112A when no calibration or compensation is performed for the absolute gain mismatch (ε) and the absolute phase mismatch (θ) in the received signal. A line “image” represents a signal with the absolute gain mismatch (ε) and the absolute phase mismatch (θ), represented as a “RSB_{raw}”. The “RSB_{raw}” refers to an initial measurement of the signal power or distortion in the communication system before any calibration or compensation is performed for the absolute gain mismatch (ε) and the absolute phase mismatch (θ). A line “desired” represents an ideal signal that should have been received without any distortion. The calibrated output 102-4C represents the signal obtained after the calibration has been applied to correct for the absolute gain mismatch (ε) and the absolute phase mismatch (θ). This corrected signal is shown as a “RSB_{cal}” via an image line in the calibrated output 102-4C. In this case, a desired line in the calibrated output 102-4C represents an ideal signal that should have been received, with the absolute gain mismatch (ε) and the absolute phase mismatch (θ) minimized during the calibration.

Further, an ADC input 104C represents a raw grid image 104-2C with the “RSB_{raw}”, and a calibrated grid image with the “RSB_{cal}”. In the raw grid image 104-2C and the calibrated grid image 104-4C, each dot represents a sample (or data) of the signal that is received at a given point in time. Further, an X-axis represents the I component of the signal. Y-axis represents the Q component of the signal. The raw grid image 104-2C represents a distorted cloud of dots that do not perfectly align along ideal points of I-Q axes (where I and Q should ideally be orthogonal, or 90 degrees apart), when no calibration or compensation for the absolute gain mismatch (ε) and the absolute phase mismatch (θ) is performed for the signal. The distortion arises due to the absolute gain mismatch (ε) and the absolute phase mismatch (θ), causing the dots to spread in a non-ideal way, leading to a less accurate signal representation. Further, the calibrated grid image 104-4C represents each dot closer to its corresponding ideal position, forming a more accurate representation of the desired signal with better alignment along the I-Q axes. The calibrated grid image 104-4C represents the signal that is generated after the calibration, or the compensation is performed using the calibration technique for any gain and phase imbalances between the I and Q components based on the absolute gain mismatch (ε) and the absolute phase mismatch (θ). The corrections performed using the calibration technique reduce the absolute gain mismatch (ε) and the absolute phase mismatch (θ) of the signal, thus improving the signal quality and reducing the RSB. The RSB of the RF front-end can be estimated using equation 1 below:

$$RSB = \frac{1 - 2 ( 1 + ε ) cos θ + {( 1 + ε )}^{2}}{1 + 2 ( 1 + ε ) cos θ + {( 1 + ε )}^{2}} \qquad ( 1 )$$

For small values of the absolute gain mismatch (ε) and the absolute phase mismatch (θ) (with ε<<1 and θ<<1 radian, or a gain mismatch (ε) of less than 1 decibel (dB) and a phase mismatch (θ) of less than 5 degrees), a reasonable approximation of the RSB may be obtained using equation 2 below:

$$R S B = \frac{{ε}^{2} + {θ}^{2}}{4} \qquad ( 2 )$$

Further, to determine the impact of the absolute gain mismatch (ε) and the absolute phase mismatch (θ) on the EVM, it is essential to relate EVM to the SNDR of the RF front-end, which is done using an equation 3 below:

$$EVM = M \approx \frac{1}{\sqrt{SNDR}} = \sqrt{\frac{1}{SNR} + IM 3 + R S B} \qquad ( 3 )$$

In the above equation 3, ‘IM3’ stands for a third-order intermodulation. Further, in the above equation 3, the RF front-end is assumed to have the ‘SNR’ in dB, the ‘IM3’ in decibels relative to carrier (dBc), and the ‘RSB’ in dBc. This relationship depicted via the above equation 3 helps us understand how the absolute gain mismatch (ε) and the absolute phase mismatch (θ) in the communication system can affect the EVM. For example, to achieve an EVM of −40 dB, one could target an SNR of 45 dB, an IM3 of −45 dBc, and an RSB of 45 dBc, which would correspond to an absolute gain mismatch (ε) of 0.1 dB and an absolute phase mismatch (θ) of 0.5 degree.

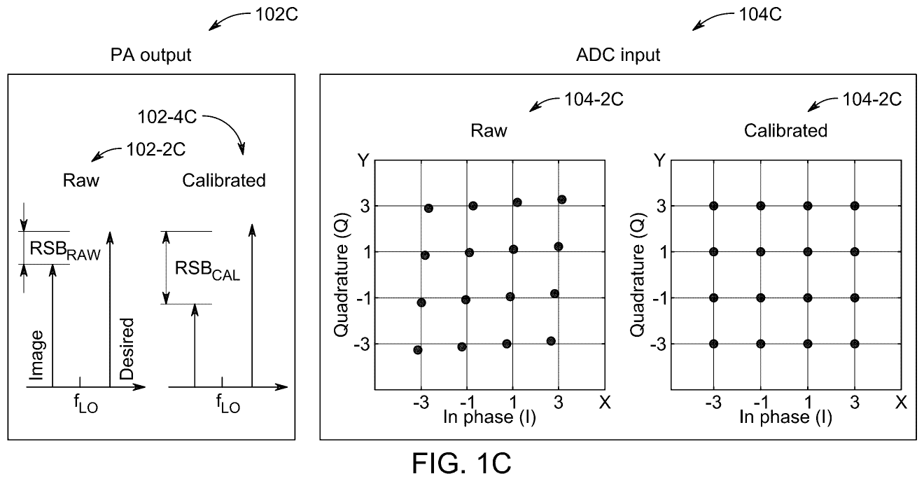

Referring now to FIG. 2, the present disclosure provides a graphical representation 200 of an EVM versus an operation power curve with an RSB, according to certain embodiments. In an embodiment, the EVM versus the operating power curve is also referred to as a bathtub curve with the RSB of −40 dBc. The EVM is a measure of a difference between a transmitted signal and a received signal, quantifying a signal distortion or an error. A lower value of the EVM indicates better signal fidelity, while a higher value of the EVM indicates greater signal distortion. The operating power (measured in decibel milliwatt (dBm)) refers to a transmission power level of the communication system during the signal transmission. The EVM typically varies with changes in the operating power, with lower power levels dominated by noise and higher power levels dominated by the signal distortion. Further, the RSB represents a level of unwanted signals or distortion relative to the desired signal, typically measured in dBc. A lower RSB value indicates a higher distortion or a noise in the received signal.

Further, as represented via the graphical representation 200, an X-axis represents the operating power of the communication system. Further, a Y-axis represents the EVM of the received signal. Further, a curved line represents the EVM versus the operating power curve, i.e., the bathtub curve. In an embodiment, as depicted via the graphical representation 200, at lower operating power levels, the communication system is primarily limited by a noise floor (depicted as “Noise limited”), which results in higher EVM values. As the operating power increases, the communication system enters a regime where the EVM is dominated by distortion (depicted as “distortion limited”), particularly from intermodulation products (e.g., the IM3) and other non-linearities. Further, the graphical representation 200 depicts a sweet spot, i.e., an EVM floor in a middle of the graphical representation 200, where the EVM stabilizes at a lower value, typically due to the I and Q imbalance (i.e., the gain and phase imbalance), which becomes a primary limiting factor. This sweet spot represents a point at which the EVM reaches its minimum value and is mainly constrained by imperfections (i.e., the gain mismatch (ε) and the phase mismatch (θ)) in the I and Q components of the received signal.

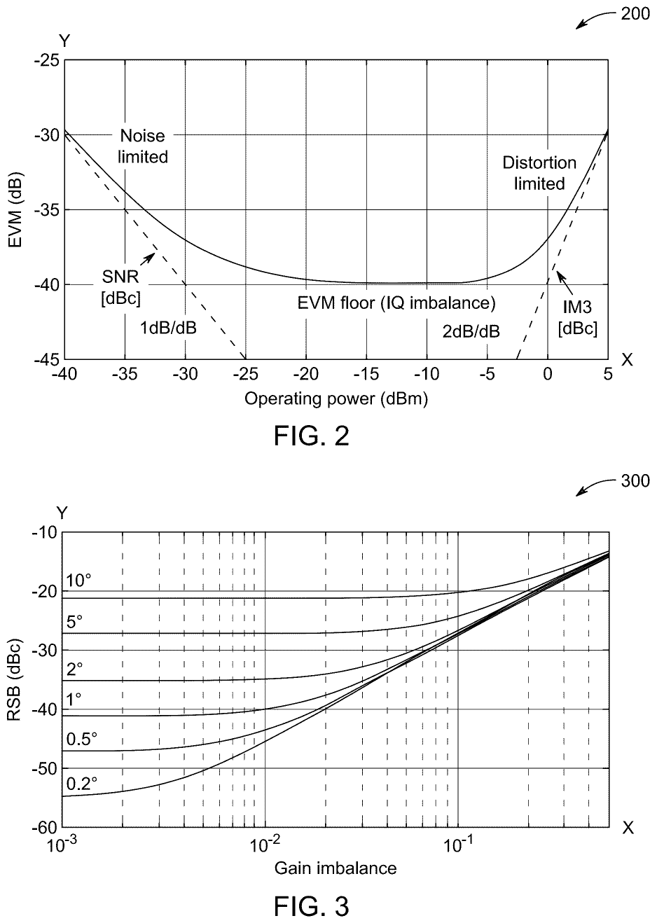

Referring now to FIG. 3, the present disclosure provides a graphical representation 300 of an RSB versus different gain mismatches and phase mismatches, according to certain embodiments. As depicted via the graphical representation 300, an X-axis represents a gain mismatch (ε) (depicted as ‘gain imbalance’). Further, Y-axis represents the RSB. Further, each curved line represents a change in a value of the RSB due to the gain mismatch (ε) and the phase mismatch (θ) (represented in degrees). For example, 0.2 degrees increasing curve line shows how the gain mismatch (ε) affects the RSB in the communication system with a minimal phase mismatch (θ) of 0.2 degrees. The 0.2 degrees increasing curve line illustrates how even small mismatches in a gain and a phase can cause the signal degradation. In particular, the graphical representation 300 illustrates how variations in the gain and the phase directly affect the RSB, highlighting the impact of the gain mismatch (ε) and the phase mismatch (θ) on the signal quality and the communication system performance. This is demonstrated for 0.5 degrees, 1 degree, 2 degree, 5 degree and 10 degree increasing curve lines.

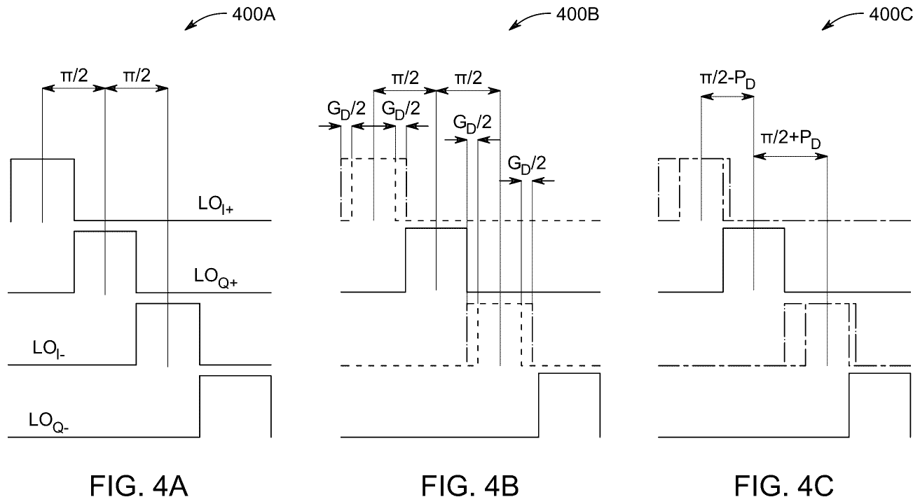

Referring now to FIG. 4A, the present disclosure provides a diagram 400A representing an ideal condition of LOs with no mismatch, according to certain embodiments. The diagram 400A shows a scenario where the LOs (i.e., the pair of LO signals) are ideal, with a 25% duty cycle and no mismatch between the pair of LO signals. In this ideal scenario, a 90° phase shift (represented as

$$\frac{π}{2} )$$

is maintained between the pair of LO signals of the I and Q components, ensuring proper signal alignment. In the diagram 400A, the pair of LO signals are represented as “LO_{I+} and LO_{Q+}”, and “LO_{I-} and LO_{Q-}”. This configuration of the diagram 400A depicts that there are no gain and phase imbalances, and the I and Q components remain perfectly orthogonal.

Referring now to FIG. 4B, the present disclosure provides a diagram 400B representing a condition with mismatched LOs for a gain calibration, according to certain embodiments. In an embodiment, to introduce gain calibration only using the on-chip passive double edge-tuning mechanism, the pulse width of either of the pair of LO signals associated with the I or Q components must be adjusted by a specific amount, e.g., a first predetermined value denoted as ‘G_{D}’ (in units of picoseconds (ps)). To adjust the pulse width, the pulse width of one of the pair of LO signals associated with one of the I component or the Q component is reduced to counterbalance any excess gain (i.e., the gain mismatch (ε)) in another component. For this, both a rising edge and a falling edge of a first LO signal (e.g., I component signal) are reduced by half of the first predetermined value, i.e., G_{D}/2, ensuring that the phase difference between the I and Q components remains at 90°. In the example of FIG. 4B, the gain calibration is performed for the I component and for both polarities of the I component. This method of introducing the gain calibration prevents any change in the phase between the I and Q components while adjusting any gain mismatch (ε), offering a precise method for the gain calibration in the communication system. The value of the first predetermined value (G_{D}) can be calculated using an equation 4.

$$G D = \frac{4 ε}{{f}_{L O}} \qquad ( 4 )$$

In the above equation 4, ‘&’ represents the gain mismatch. Further, ‘f_{LO}’ represents the operation frequency of a LO (example the LO generator 110A or the LO generator 110B). For example, to achieve a gain mismatch calibration of 10 milli-dB (m), a delay resolution required for each of the rising edge and the falling edge of the first LO signal may be 1.25 ps with a 1 Gigahertz (GHz) LO operation frequency.

Referring now to FIG. 4C, the present disclosure provides another exemplary diagram 400C representing a condition with mismatched LOs for a gain calibration and a phase calibration, according to certain embodiments. The exemplary diagram 400C illustrates a process of adding a phase calibration using the on-chip passive double edge-tuning mechanism, without affecting the gain calibration (for example, the gain calibration achieved in FIG. 4B). The addition of the phase calibration can be accomplished by introducing a second predetermined value, P_{D} (in units of radians (rad)) to both positive and negative polarities (also referred to as positive and negative LO pulses) to one of the pair of LO signals, while maintaining a specified orthogonality (e.g., a 180° phase shift) between the pair of LO signals. In other words, the phase mismatch (θ) is compensated by shifting the phase of the first LO signal (e.g., I component) by the second predetermined value, P_{D}, without changing the phase shift of the first LO signal. In the example of FIG. 4C, the phase calibration is performed for the I component and for both polarities of the I component.

In an embodiment, the second predetermined value, P_{D}, is an absolute phase mismatch (θ) of the RF front-end. A new phase shift between the I and Q components is 90°-P_{D}, where

$${P}_{D} = θ . \qquad ( 5 )$$

In an embodiment, the second predetermined value, P_{D}, can have both positive and negative values, depending on whether the phase shift needs to be increased or decreased. For example, to achieve a phase calibration of 0.5°, a delay resolution of 1.38 picoseconds (ps) may be needed, assuming a 1 GHz LO operation frequency. This process of performing the phase calibration allows precise phase calibration while maintaining the achieved gain calibration, ensuring that both gain and phase mismatches can be independently controlled in the communication system.

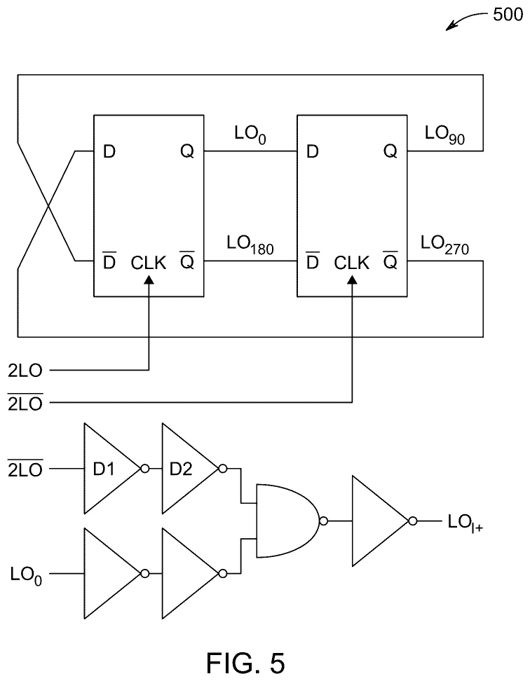

Referring now to FIG. 5, the present disclosure provides a diagram representing a circuit 500 with the on-chip passive double-edge tuning mechanism, according to certain embodiments. The circuit 500 represents a non-overlapping 25% duty cycle LO generation, along with an addition of a dual-edge tuning delay cell. A first inverter “D1” (also referred to as a first inverter-based circuit) is responsible for adjusting the rising edge timing. In other words, the first inverter “D1” is configured for adjusting the rising edge of the first LO signal of the pair of LO signals. Further, a second inverter “D2” (also referred to as a second inverter-based circuit) is dedicated to adjusting the timing of the falling edge of the first LO signal. The circuit 500 specifically shows a process for the I-LO signal (represented as LO_{I+}). As depicted via the circuit 500, in some embodiments, approximately 8 delay cells (also referred to as the set of edge-tunable delay cells) may be required to implement the on-chip passive double-edge tuning mechanism. The set of edge-tunable delay cells may be configured to passively modify the pulse width and the phase of the first LO signal of the pair of LO signals to compensate for the gain mismatch (ε) or the phase mismatch (θ).

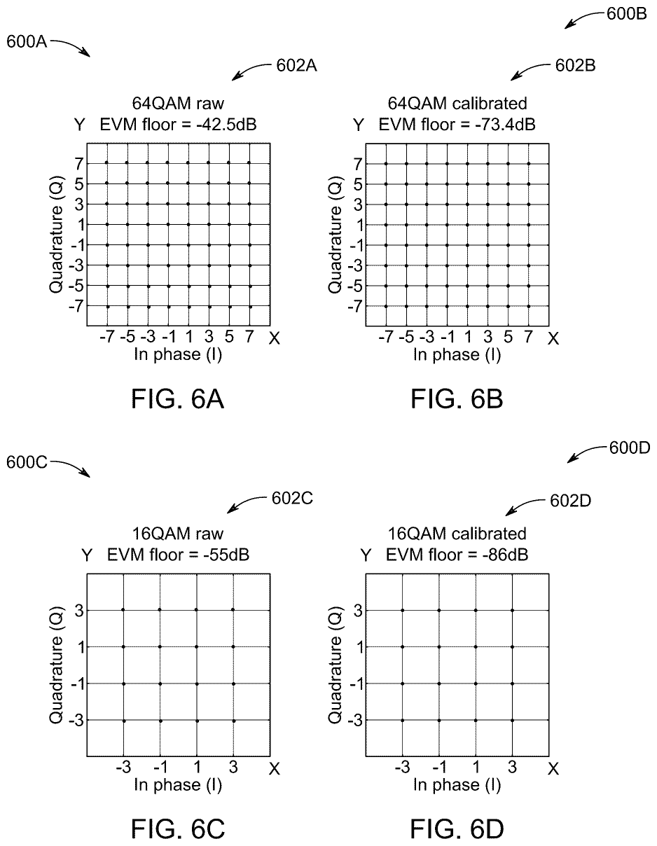

Referring now to FIG. 6A, the present disclosure provides an exemplary diagram 600A depicting an EVM floor for a raw I and Q imbalance for 64 Quadrature Amplitude Modification (QAM), according to certain embodiments. In particular, the exemplary diagram 600A represents a simulated EVM for a modulation scheme (e.g., 64 QAM), taking into account a gain mismatch (ε) of 0.25 dB and a phase mismatch (θ) of 0.5° in the presence of the I and Q imbalance (also referred to as the gain and phase imbalance). The simulation assumes a 1 GHz operation carrier frequency and a 5 MHz channel bandwidth. In an embodiment, the QAM is defined as a method of combining both an amplitude modulation (AM) and a phase modulation (PM) to encode data onto a carrier signal. As shown in the exemplary diagram 600A, a grid 602A represents the raw I and Q imbalance with 64 QAM. An X-axis of the grid 602A represents the I component, while a Y-axis of the grid 602A represents the Q component. Further, the grid 602A shows a raw EVM floor of −42.5 dB that is observed for the raw I and Q imbalance of 64 QAM when no calibration is performed.

Referring now to FIG. 6B, the present disclosure provides an exemplary diagram 600B depicting an EVM floor for a calibrated I and Q imbalance for 64 QAM, according to certain embodiments. In particular, the exemplary diagram 600B represents a simulated EVM for a modulation scheme (e.g., 64 QAM), taking into account the gain mismatch (ε) of 0.25 dB and the phase mismatch (θ) of 0.5° in the presence of the I and Q imbalance (also referred to as the gain and phase imbalance). The simulation assumes the 1 GHz operation carrier frequency and the 5 MHz channel bandwidth. Further, a grid 602B represents the calibrated I and Q imbalance with 64 QAM. An X-axis of the grid 602B represents the I component, while a Y-axis of the grid 602B represents the Q component. Further, the grid 602B shows a calibrated EVM floor of −73.4 dB that is observed for the calibrated I and Q imbalance of 64 QAM when the calibration is performed using the on-chip passive double-edge tuning mechanism.

Referring now to FIG. 6C, the present disclosure provides an exemplary diagram 600C depicting an EVM floor for a raw I and Q imbalance for 16 QAM, according to certain embodiments. In particular, the exemplary diagram 600C represents a simulated EVM for a modulation scheme (e.g., 16 QAM), taking into account the gain mismatch (ε) of 0.25 dB and the phase mismatch (θ) of 0.5° in the presence of the I and Q imbalance (also referred to as the gain and phase imbalance). The simulation assumes the 1 GHz operation carrier frequency and the 5 MHz channel bandwidth. In an embodiment, the grid 602C represents the raw I and Q imbalance with 16 QAM. An X-axis of the grid 602C represents the I component, while a Y-axis of the grid 602C represents the Q component. Further, the grid 602C shows a raw EVM floor of −55 dB that is observed for the raw I and Q imbalance of 16 QAM when no calibration is performed.

Referring now to FIG. 6D, the present disclosure provides an exemplary diagram 600D depicting an EVM floor for a calibrated I and Q imbalance for 16 QAM, according to certain embodiments. In particular, the exemplary diagram 600D represents a simulated EVM for a modulation scheme (e.g., 16 QAM), taking into account the gain mismatch (ε) of 0.25 dB and the phase mismatch (θ) of 0.5° in the presence of the I and Q imbalance (also referred to as the gain and phase imbalance). The simulation assumes the 1 GHz operation carrier frequency and the 5 MHz channel bandwidth. Further, a grid 602D represents the calibrated I and Q imbalance with 16 QAM. An X-axis of the grid 602D represents the I component, while a Y-axis of the grid 602D represents the Q component. Further, the grid 602D shows a calibrated EVM floor of −86 dB that is observed for the calibrated I and Q imbalance of 16 QAM when the calibration is performed using the on-chip passive double-edge tuning mechanism.

In an embodiment, an EVM floor refers to a lowest achievable EVM level (i.e., a level of distortion or error) in the communication system. The EVM floor represents a baseline distortion in the received signal caused by various imperfections, such as the I and Q imbalance (both the gain mismatch (ε) and the phase mismatch (θ)), even when no further signal corrections are made. A raw EVM floor (e.g., the raw EVM floor depicted via the grid 602A and the raw EVM floor depicted via the grid 602C) corresponds to an EVM that is observed when no correction is performed for the I and Q imbalance, i.e., when the on-chip passive double edge tuning mechanism is not executed. Further, a calibrated EVM floor (e.g., the calibrated EVM floor depicted via the grid 602B and the calibrated EVM floor depicted via the grid 602D) corresponds to an EVM that is observed after corrective measures, such as an I and Q calibration are applied using the on-chip passive double-edge tuning mechanism to mitigate the gain mismatch (ε) and the phase mismatch (θ). The calibration performed using the on-chip passive double-edge tuning mechanism improves an accuracy of the received signal by compensating for the gain mismatch (ε) and the phase mismatch (θ), reducing the EVM floor. As depicted via the exemplary diagrams 600B and 600D, after performing the calibration, the EVM floor is much lower, meaning the distortion (i.e., the gain and phase imbalance) in the received signal is reduced. The improvement in the distortion of the received signal after performing the calibration is more significant in higher-order modulation schemes, like 64 QAM. In particular, with the proposed on-chip passive double-edge tuning mechanism, the EVM floor for 16 QAM and 64 QAM are improved by 30.9 dB and 31 dB, respectively.

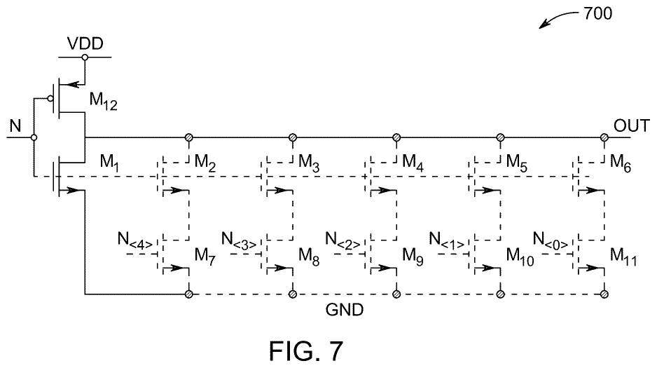

Referring now to FIG. 7, the present disclosure provides a diagram 700 depicting an inverter with an on-chip passive double-edge tuning mechanism, according to certain embodiments. In particular, the diagram 700 shows the inverter that incorporates various skew factors to modify the timing of output signal edges (e.g., the rising edge and the falling edge of the first LO signal) by adjusting the fall times. In particular, the diagram 700 represents inverter-based circuits with skew factors that allow for controlling a magnitude of the pulse width and the phase shift of the rising edge and the falling edge of the first LO signal of the pair of LO signals. The inverter-based circuits with skew factors are integrated within the set of edge-tunable delay cells. As depicted via the exemplary diagram 700, the inventor-based circuit includes various transistors (also referred to as pull up transistors) labeled as M1, M2, M3, M4, M5, M6, M7, M8, M9, M10, M11, and M12. In an embodiment, ‘M’ is used to denote Metal-Oxide-Semiconductor Field-Effect Transistors (MOSFETs). Further, each transistor (e.g., M1, M2, . . . , M12) plays a role in controlling or adjusting the rising edge and the falling edge delays at specific points in the inverter-based circuit, contributing to the overall tuning mechanism for the phase shift and pulse width control of the first LO signal.

In an embodiment, the inverter refers to a basic logic gate that inverts an input signal, i.e., the received signal, producing an output signal (i.e., the first LO signal) that is opposite to the received input signal. For example, if the input signal is high, the output signal will be low, and vice versa. Further, the skew factors refer to an intentional delay introduced into the rising edge and the falling edge of the output signal. The delay introduced can be controlled to adjust the timing of these rising and falling edges, which is important for calibration purposes or to compensate for any I and Q imbalances in the communication system. Further, the fall times refer to the durations, the invertor takes for the input signal to transition from a high state to a low state.

In an embodiment, a 5-bit N-code (i.e., the calibration codes) control is used to adjust the timing of the falling edge of the output signal. The 5-bit N-code means there are 32 possible values (representing 32 different combinations of 1s and 0s), allowing for precise control over the delay or the skew introduced in the input signal. In other words, the calibration codes, i.e., a 5-bit N-code (also referred to as the 5-bit code) allows control of delays of the rising edge or the falling edge of the first LO signal of the pair of LO signals in sub-picosecond (ps) resolution.

Further, this control mechanism using the 5-bit N-code is used to fine-tune the rising edge and the falling edge of the output signal, which can be adjusted depending on the requirements (e.g., a phase noise mitigation, a modulation scheme optimization, a channel equalization, etc.) of the communication system. Further, to adjust the timing of the rising edge or the falling edge of the output signal, a bit width (also referred to as the pulse width) can be increased for higher resolution and/or a broader range of control if needed, depending on the specific requirements of the standard, as indicated by equations 4 and 5. Further, in some embodiments, for adjusting the rising edge and the falling edge, a default control code is set to a midpoint (e.g., 16-bit code or 10000) to enable tuning of both the rising edge and falling edge in either direction. For instance, by using the midpoint of the 5-bit N-code, the communication system can be tuned symmetrically in both directions (i.e., the rising edge and the falling edge). The usage of the midpoint ensures that the adjustment of the rising edge and the falling edge can be done evenly, allowing for equal timing control in both directions.

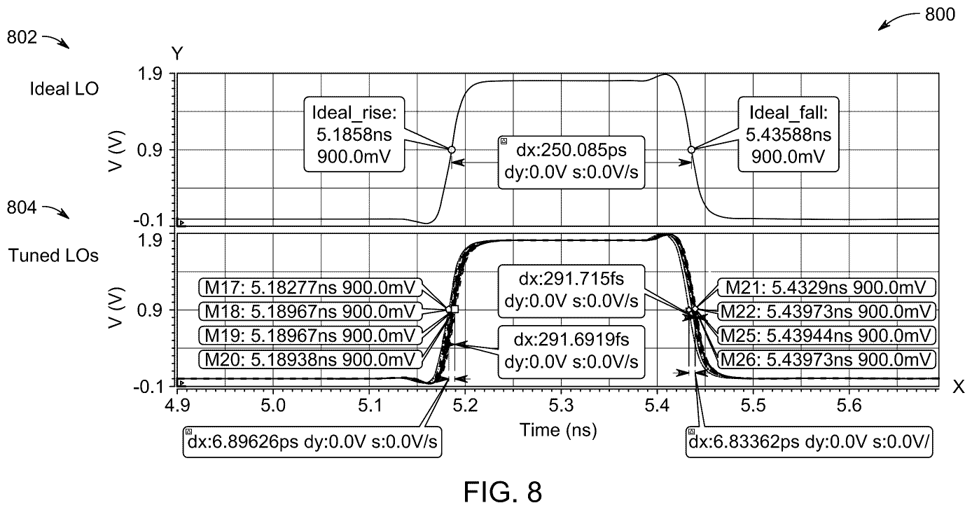

Referring now to FIG. 8, the present disclosure provides an exemplary diagram 800 depicting a transient simulation for an ideal LO and mismatched LOs with different tuning codes, according to certain embodiments. As depicted via the exemplary diagram 800, a graph depicting the transient simulation for an ideal LO signal 802 and mismatched LO signals (represented as tuned LO signals 804) that are adjusted using different tuning codes is shown. In other words, the graph shows waveform characteristics of the ideal LO signal 802 and the tuned LO signals. An X-axis of the graph represents a time progression (in nanoseconds (ns)) of the ideal LO signal 802 (also referred to as the input signal or the received signal) and the tuned LO signals 804 (i.e., the mismatched LO signals, the output signals, or the pair of LO signals) over a period. The time progression indicates a timescale over which the rising edge and the falling edge of each LO signal (i.e., the ideal LO signal 802 and the mismatched LO signals) are observed and adjusted during the simulation. Further, a Y-axis represents the voltage (V) levels of each LO signal. The voltage levels indicate each LO signal's amplitude at any given point in time, showing how each LO signal transitions between the high state and the low state as the rising edge and the falling edge are adjusted.

Further, as depicted via the graph in FIG. 8, for the ideal LO signal 802, a waveform typically has clean and symmetrical rising and falling edges with no distortion, representing an ideal signal without calibration. In contrast, waveforms of the tuned LO signals 804 shows adjustments to the rising and falling edges, based on an applied tuning code (i.e., a calibration code), which compensates for any imperfections like the gain mismatch (ε) and the phase mismatch (θ) in each tuned LO signal. In particular, the graph illustrates a simulated pulse at the midpoint of the 5-bit N-code (with calibration disabled) as well as various instances where the rising and falling edges are adjusted using different calibration codes. The simulation in the graph demonstrates a resolution of better than 0.3 ps and a tuning range of at least 6.8 ps for each edge. In an embodiment, this resolution and the tuning range for each edge translates to a gain mismatch resolution of approximately 10 m dB and a phase mismatch resolution of 0.1°, both at the operation frequency of 1 GHz.

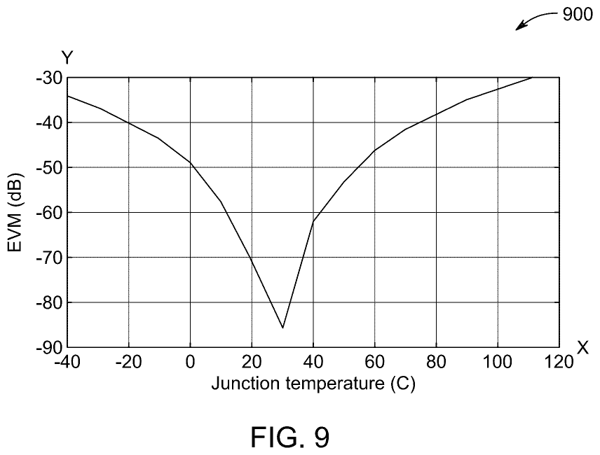

Referring now to FIG. 9, the present disclosure provides a diagram 900 representing a graph depicting an EVM of a calibrated I and Q balance for a Quadrature Phase Shift Keying (QPSK) modulation versus temperature, according to certain embodiments. In particular, the graph shows a simulation of a calibrated EVM for the QPSK modulation versus the temperature. As represented via the diagram 900, an X-axis of the graph represents a junction temperature (measured in Celsius (C)). In particular, the X-axis axis represents a temperature range over which the EVM is measured. Further, a Y-axis of the graph represents the calibrated EVM (measured in dB). Further, a curve line corresponding to the X-axis and the Y-axis represents how the calibrated EVM changes as the temperature of the communication system increases or decreases. For example, as shown via the curve line in the graph, at approximately 30 degrees C. temperature, the EVM is optimized (i.e., the EVM is observed to be lowest), and as the temperature increases beyond a specific threshold, e.g., 60 degrees C., the EVM starts to degrade, indicating a worsening of the quality of the output signal (i.e., the first LO signal) due to factors such as temperature-induced changes in the communication system's components (such as the I and Q imbalance).

In an embodiment, the calibration code (i.e., the 5-bit N-code or the 5-bit code) is initially trimmed at room temperature, where the EVM is optimized. The calibration code refers to a set of digital control values or parameters used to adjust and correct certain imperfections in the communication system, such as the gain mismatch (ε) and the phase mismatch (θ) in the I and Q components of the signal. As depicted via the graph, a calibration technique (i.e., the on-chip passive double edge-tuning mechanism) may become temperature-sensitive beyond approximately 60° C., indicating that the calibration code needs to be adjusted to account for temperature variations. This degradation is the result of a duty cycle distortion caused by changes in the temperature affecting a circuit of the inverter. In an embodiment, the calibration code is provided by a controller to the set of edge-tunable delay cells for adjusting gain and phase imbalances based on the gain mismatch (ε) and the phase mismatch (θ). The controller is configured to determine a gain adjustment and a phase adjustment based on the gain mismatch (ε) and the phase mismatch (θ), respectively. Further, the controller is configured to determine the calibration codes for achieving the gain adjustment and the phase adjustment. Once the calibration codes are determined, the controller is configured to provide the calibration codes to the inverter-based circuits with skew factors to adjust the pulse width and the phase shift of the first LO signal to compensate for the gain mismatch (ε) and the phase mismatch (θ).

In some embodiments, since an I and Q chain imbalance itself is a function of the temperature, hence the calibration codes need to be applied across the temperature to ensure optimal performance. In an embodiment, a power consumption difference is code-dependent and on average is negligible, when enabling a calibration mode. Further, using the on-chip passive double edge-tuning mechanism disclosed in present disclosure, the power consumption of LO signal generation (due to dynamic switching of the inverter) is reduced by approximately 60 microwatts (μW). Further, assuming extreme calibration codes, the total RF chain power is expected to change by approximately 0.15 milliwatt (mW). In addition, an estimated increase in a calibration area due to added switches is less than 20 μm² (active area), which is lower than existing prior arts. A Table 1 below shows a comparative summary of the calibration technique (i.e., on-chip passive double edge-tuning mechanism) disclosed in the present disclosure against state-of-the-art methods (i.e., the existing prior arts) dedicated to image rejection at various points in a communication channel.

TABLE 1

| | Proposed | | | | |
|---|---|---|---|---|---|
| | calibration | TCAS-II | VLSI | JSSC | JSSC |
| | technique | (2018) | (2019) | (2003) | (2015) |
| Verification | Simulation | Measurement | Simulation | Measurement | Measurement |
| | (180 nm) | (130 nm) | (NA) | (250 nm) | (45 nm) |
| Technique | LO Double | LO bias | Off-chip | LO delay and | Digital |
| | Edge-Tuning | tuning | | Gain Tuning | Calibration |
| Domain | RF Tx | RF Tx | Baseband | RF and | Digital |
| | and Rx | | (BB) Tx | BB Rx | post ADC |
| Calibration | ̆0.15 ≈ 0^{α} | 1 | NA | 5 | NA |
| Power (mW) | | | | | |
| Calibration | 0.02 *10⁻³ | 0.025 | NA | 5 | NA |
| area (mm²) | | | | | |
| RSB (dBc) | −73.4@64QAM | −60.4@64QAM | −50.3@NA | −57.3@NA | −70@64QAM^{b} |
| Frequency | 1 | 2 | 1 | 2 | 2.2 |
| (GHz) | | | | | |
| Bandwidth | 5 | 10 | 10 | 1 | 5 |
| (MHz) | | | | | |

In Table 1 above each row of first column represents a name of a work (i.e., the calibration technique of the disclosure and a corresponding state of art work). As depicted via the Table 1, the state-of-the-art work (i.e., the existing prior arts) include:
1. TCAS-II—W. Zhang, H. He, and R. Wan, “A 2.0 GHz IQ Imbalance Compensator With Programmable Switch Biases in a Passive Mixer,” in IEEE Transactions On Circuits And Systems—II: Express Briefs, vol. 65, pp. 2694-274 August 2018.
2. VLSI (2019): J. Kim, H.-S. Jo, K.-J. Lee, D.-H. Lee, D.-H. Choi, and S. Kim, “A Low-Complexity I/Q Imbalance Calibration Method for Quadrature Modulator,” in IEEE Transactions On Very Large Scale Integration (VLSI) Systmes, vol. 27, pp. 974-977, April 2019.
3. JSSC 2003: L. Der and B. Razavi, “A 2-GHz CMOS image-reject receiver with LMS calibration,” in IEEE Journal Solid-State Circuits, vol. 38, p. 167-175, February 2003.
4. JSSC 2015: S. C. Hwu and B. Razavi, “An RF receiver for intra-band carrier aggregation,” in IEEE Journal Solid-State Circuits, vol. 50, p. 946-961, April 2015.

Further, each column of a second row “verification” represents how a calibration technique that is applied is verified in each respective work. For example, “Simulation (180 nm)” refers to simulations conducted using a 180 nm Complementary Metal-Oxide-Semiconductor (CMOS process). Each column of a third row “technique” refers to a specific method used for calibration in each work. For example, LO double edge-tuning (i.e., the on-chip passive double-edge tuning mechanism) refers to a technique that adjusts the rising and falling edges of LO signals (i.e., the pair of LO signals) for better calibration. Each column of a fourth row “domain” specifies whether the calibration technique is applied to the RF Tx, BB Tx, or reception domains, or if it is digital post-ADC. Further, each column of a fifth row “calibration power (mW)” represents the power consumption by the calibration technique in mW. Each column of a sixth row “calibration area (mm2)” indicates an area used for a calibration circuitry in each work. Each column of a seventh row “RSB (dBc)” represents a spurious signal power relative to a desired signal, showing the signal quality after the calibration. Each column of an eighth row “frequency (GHz)” represents a frequency at which the communication system operates. Each column of a ninth row “Bandwidth (MHz)” represents a bandwidth of the communication channel used for the communication system

Further, as depicted via the Table 1, the proposed calibration technique can be seamlessly integrated alongside other existing analog and digital domain calibration techniques (i.e., the existing state of art work) while maintaining minimal impact on overall power consumption and chip area. Notably, improvements in resolution, operating frequency, area efficiency, and power budget are anticipated using the proposed calibration technique. This proposed calibration technique is expected to offer significant benefits as a technology continues to advance.

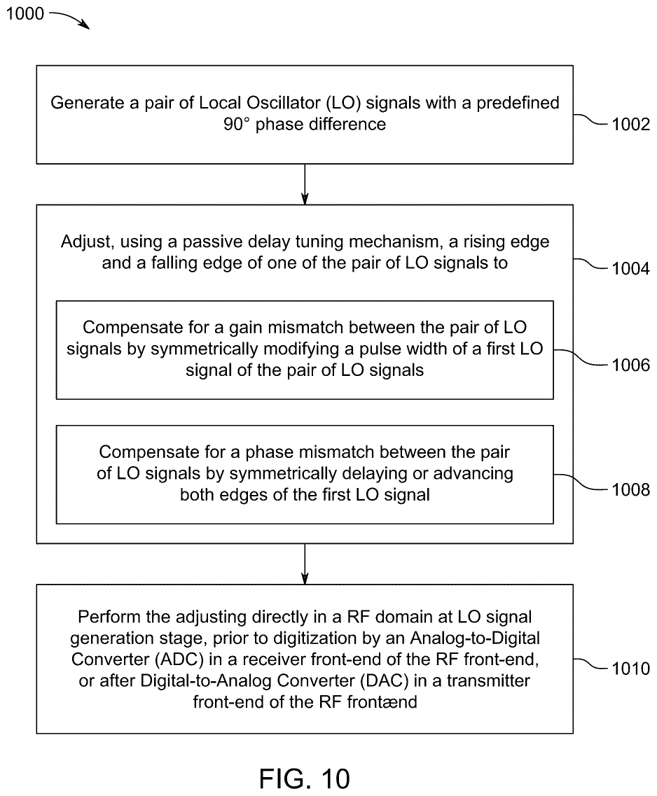

Referring now to FIG. 10, a diagram 1000 of a method of negating a hardware mismatch in the RF front-end with an on-chip passive double edge-tuning mechanism, according to certain embodiments. In order to negate the hardware mismatch in the RF front-end with the on-chip passive double-edge tuning mechanism, at step 1002, the pair of LO signals are generated with the predefined 90° phase difference. In an embodiment, the pair of LO signals includes I-LO signals and Q-LO signals. In other words, one of the pair of LO signals may correspond to an LO signal associated with the I component and another LO signal may correspond to an LO signal associated with the Q component. Once the pair of LO signals are generated, at step 1004, the rising edge and the falling edge of one of the pair of LO signals are adjusted using the passive delay tuning mechanism. In an embodiment, the rising edge and the falling edge are adjusted independently using edge-tunable inverters (also referred to as the inverter-based circuits with skew factors, e.g., the invertor shown in FIG. 7) of the passive delay tuning mechanism. In other words, the passive delay tuning mechanism is used to modify the timing of the rising edge and the falling edge of one of the pair of LO signals, in order to address any gain or phase mismatches.

Further, to adjust one of the pair of LO signals as mentioned via the step 1004, at step 1006, the gain mismatch (ε) between the pair of LO signals is compensated by symmetrically modifying the pulse width of a first LO signal of the pair of LO signals. In an embodiment, the first LO signal further includes a positive LO pulse and a negative LO pulse. The positive LO pulse refers to a part of the first LO signal that represents the rising edge of the first LO signal, where the voltage (V) increases from the low state to the high state. Further, the negative LO pulse refers to a part of the first LO signal that represents the falling edge of the first LO signal, where the voltage (V) decreases from the high state to the low state. In an embodiment, the gain mismatch (ε) is compensated by reducing the pulse width for the first LO signal. The pulse width of the first LO signal is reduced to balance a relative amplitude difference between the pair of LO signals.

In an embodiment, the gain mismatch (ε) is compensated by reducing the pulse width of the first LO signal by a first predetermined value G_{D}. In particular, each of the rising edge and the falling edge of the first LO signal is reduced by the half of the first predetermined value, G_{D}/2. In an embodiment, the first predetermined value, G_{D}, is determined as G_{D}=48/f_{LO}, where ε is the absolute gain mismatch of the RF front-end, and the f_{LO} is the operation frequency of the RF front-end. Further, the first predetermined value G_{D} refers to a specific delay amount, typically measured in ps, that is calculated to compensate for the gain mismatch (ε) between the pair of LO signals. This first predetermined value G_{D} is predetermined based on a desired calibration and is derived from the requirements of the communication system, such as an operating frequency and an amount of gain imbalance. The first predetermined value G_{D} ensures that the pulse width of the first LO signal is adjusted by an amount that balances the amplitude difference between the pair of LO signals associated with the I and Q components respectively, thus mitigating the gain mismatch (ε).

Further, to adjust one of the pair of LO signals as mentioned via the step 1004, at step 1008, the phase mismatch (θ) between the pair of LO signals is compensated by symmetrically delaying or advancing both rising and falling edges of the first LO signal. In an embodiment, the phase mismatch (θ) is compensated by shifting the phase of the first LO signal symmetrically for both positive and negative polarities to maintain the specified orthogonality between the pair of LO signals. Further, the phase of the first LO signal is shifted by the second predetermined value, P_{D}, without changing the phase shift of the first LO signal. The second predetermined value, P_{D}, is the absolute phase mismatch (θ) of the RF front-end.

In an embodiment, to adjust the rising edge and the falling edge of the first LO signal of the pair of LO signals for compensating the gain mismatch (ε) or the phase mismatch (θ) to modify the pulse width and the phase of the first LO signal is performed using the set of edge-tunable delay cells. For this, the set of edge-tunable delay cells is configured to receive the calibration code from the controller (e.g., implemented as part of the double edge-tuning mechanism 108 or the inverter-based circuit depicted in FIG. 7). To determine the calibration codes, the controller is configured to initially determine the gain adjustment and the phase adjustment based on the gain mismatch (ε) or the phase mismatch (θ), respectively. Further, the controller is configured to determine the calibration codes for achieving the gain adjustment and the phase adjustment. In an embodiment, the calibration code is the 5-bit code (i.e., the 5-bit N-code) that allows control of delays of the rising edge or the falling edge of the first LO signal of the pair of LO signals in sub-picosecond resolution.

Once the rising edge and the falling edge of one of the pair of LO signals are adjusted, at step 1010, the adjustment is directly performed in the RF domain at LO signal generation stage, prior to digitization by the ADC in a receiver front-end of the RF front-end, or after DAC in the transmitter front-end of the RF front-end. In an embodiment, the adjustment performed in the RF domain reduces RSB levels and EVM without introducing additional power-hungry or computationally intensive circuitry. In some embodiments, by compensating the gain mismatch or the phase mismatch in a RF domain before analog-to-digital conversion, the SNDR requirements on subsequent ADCs in a receiver front-end of the RF front-end is reduced.

In an embodiment, the disclosure presents a method and an apparatus that negates the hardware mismatch in the RF front-end with the on-chip passive double edge-tuning mechanism (also referred to as the calibration technique or the passive delay tuning mechanism). The on-chip passive double edge-tuning mechanism disclosed in the present disclosure is used to modulate the timing of the rising edge and the falling edge of LO signals (i.e., the pair of LO signals), achieving minimal power consumption. Due to a passive nature of the proposed on-chip passive double edge-tuning mechanism, the calibration area increase is negligible. Further, the proposed on-chip passive double edge-tuning mechanism can be seamlessly integrated with existing analog and/or digital calibration approaches. The proposed on-chip passive double edge-tuning mechanism has been validated using the CMOS 180 nm process, demonstrating a calibration performance of better than-73 dB RSB for 64 QAM modulation at 1 GHz and the 5 MHz bandwidth. Further, the LO generation model (i.e., the LO generator) used in the simulation is based on an RF Field-Effect Transistor (FET) model, which also includes parasitic effects due to routing.

Further, the proposed on-chip passive double edge-tuning mechanism is scalable, with substantial improvements when implemented on shorter process nodes. Additionally, since the cancellation (i.e., the correction of the I and Q imbalances) occurs in the RF domain using the proposed on-chip passive double edge-tuning mechanism, there is no impact on the ADC SNDR, resulting in a significant reduction in overall power consumption. Although, in the present disclosure, the proposed on-chip passive double edge-tuning mechanism is specifically applied for the gain mismatch (ε) and the phase mismatch (θ), the proposed on-chip passive double edge-tuning mechanism has broader potential applications, including second-order modulation (IM2) distortion calibration, carrier aggregation structures, and low intermediate frequency (IF) transceivers.

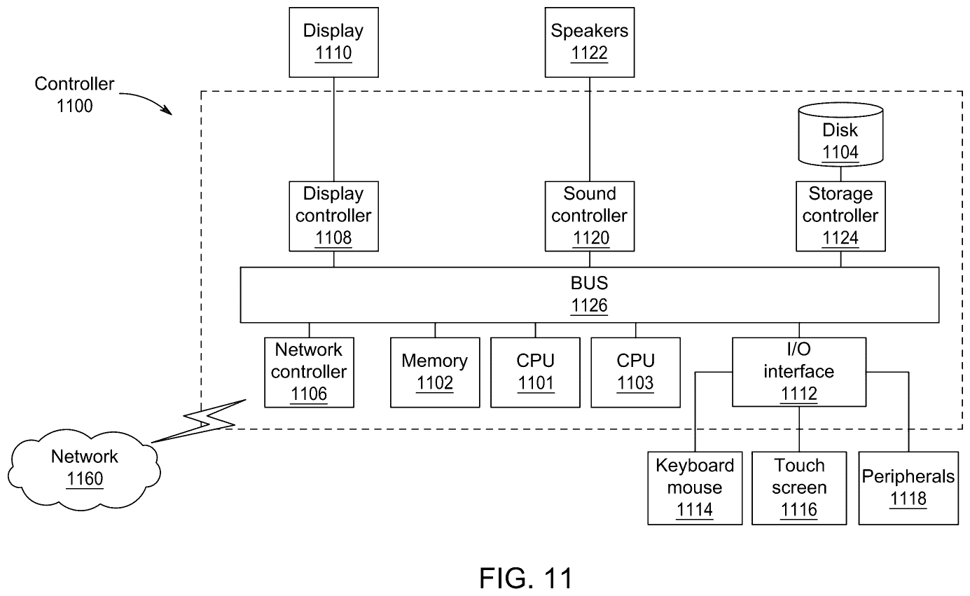

Next, further details of the hardware description of the computing environment according to exemplary embodiments is described with reference to FIG. 11. In FIG. 11, a controller 1100 is described as representative of the controller 114B in which the controller 1100 is a computing device which includes a Central Processing Unit (CPU) 1101 which performs the processes described above/below. The process data and instructions may be stored in a memory 1102. These processes and instructions may also be stored on a storage medium disk 1104 such as a Hard Disk Drive (HDD) or a portable storage medium or may be stored remotely.

Further, the claims are not limited by the form of the computer-readable media on which the instructions of the inventive process are stored. For example, the instructions may be stored on Compact Disks (CDs), Digital Versatile Discs (DVDs), in a Flash memory, a Random Access Memory (RAM), a Read-Only Memory (ROM), a Programmable Read-Only Memory (PROM), an Erasable Programmable Read-Only Memory (EPROM), an Electrically Erasable Programmable Read-Only Memory (EEPROM), a hard disk or any other information processing device with which the computing device communicates, such as a server or a computer.

Further, the claims may be provided as a utility application, background daemon, or component of an operating system, or combination thereof, executing in conjunction with the CPU 1101, a CPU 1103 and an operating system such as a Microsoft Windows 7, a Microsoft Windows 10, a UNIX, a Solaris, a LINUX, an Apple MAC-OS and other systems known to those skilled in the art.

The hardware elements in order to achieve the computing device may be realized by various circuitry elements, known to those skilled in the art. For example, the CPU 1101 or the CPU 1103 may be a Xenon or a Core processor from Intel of America or an Opteron processor from Advanced Micro Devices (AMD) of America, or may be other processor types that would be recognized by one of ordinary skill in the art. Alternatively, the CPU 1101, the CPU 1103 may be implemented on a Field-Programmable Gate Array (FPGA), an Application-Specific Integrated Circuit (ASIC), a Programmable Logic Device (PLD) or using discrete logic circuits, as one of ordinary skill in the art would recognize. Further, the CPU 1101, the CPU 1103 may be implemented as multiple processors cooperatively working in parallel to perform the instructions of the inventive processes described above.

The computing device in FIG. 11 also includes a network controller 1106, such as an Intel Ethernet Professional (PRO) network interface card from an Intel Corporation of America, for interfacing with a network 1160. As can be appreciated, the network 1160 can be a public network, such as the Internet, or a private network such as a Local Area Network (LAN) or a Wide Area Network (WAN), or any combination thereof and can also include a Public Switched Telephone Network (PSTN) or an Integrated Services Digital Network (ISDN) sub-networks. The network 1160 can also be wired, such as an Ethernet network, or can be wireless such as a cellular network including EDGE, Third Generation (3G) and Fourth Generation (4G) wireless cellular systems. The wireless network can also be a WiFi, a Bluetooth, or any other wireless form of communication that is known.

The computing device further includes a display controller 1108, such as a NVIDIA GeForce Giga Texel Shader eXtreme (GTX) or a Quadro graphics adaptor from a NVIDIA Corporation of America for interfacing with a display 1110, such as a Hewlett Packard HPL2445w Liquid Crystal Display (LCD) monitor. A general purpose I/O interface 1112 interfaces with a keyboard and/or mouse 1114 as well as a touch screen panel 1116 on or separate from display 1110. The general purpose I/O interface 1112 also connects to a variety of peripherals 1118 including printers and scanners, such as an OfficeJet or DeskJet from HP.

A sound controller 1120 is also provided in the computing device such as a Sound Blaster X-Fi Titanium from Creative, to interface with speakers/microphone 1122 thereby providing sounds and/or music.

A general purpose storage controller 1124 connects the storage medium disk 1104 with a communication bus 1126, which may be an Industry Standard Architecture (ISA), an Extended Industry Standard Architecture (EISA), a Video Electronics Standards Association (VESA), a Peripheral Component Interconnect (PCI), or similar, for interconnecting all of the components of the computing device. A description of the general features and functionality of the display 1110, keyboard and/or mouse 1114, as well as the display controller 1108, the general purpose storage controller 1124, the network controller 1106, the sound controller 1120, and the general purpose I/O interface 1112 is omitted herein for brevity as these features are known.

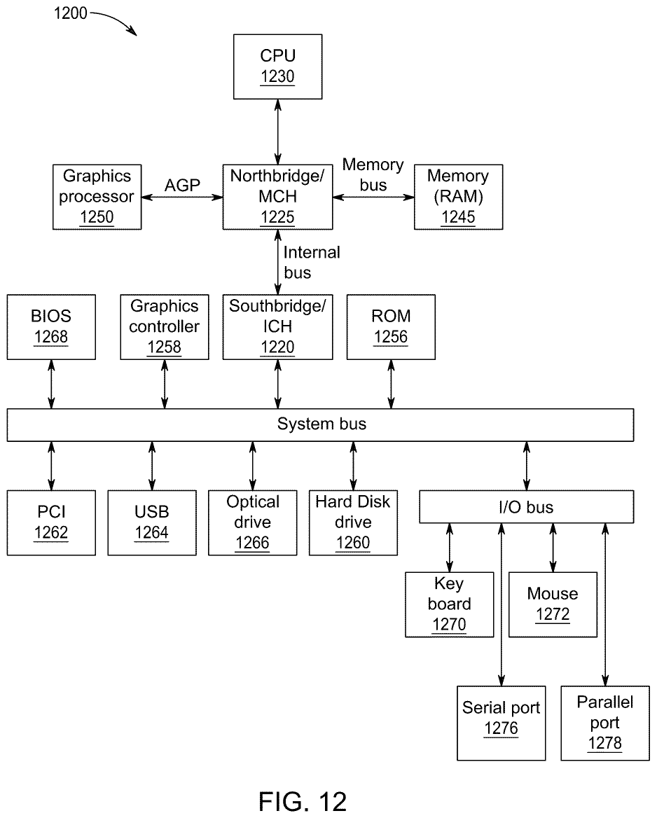

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 12.

FIG. 12 shows a schematic diagram of a data processing system 1200, according to certain embodiments, for performing the functions of the exemplary embodiments. The data processing system 1200 is an example of a computer in which code or instructions implementing the processes of the illustrative embodiments may be located.

In FIG. 12, the data processing system 1200 employs a hub architecture including a North Bridge and a Memory Controller Hub (NB/MCH) 1225 and a south bridge and an Input/Output (I/O) Controller Hub (SB/ICH) 1220. The CPU 1230 is connected to the NB/MCH 1225. The NB/MCH 1225 also connects to a memory 1245 via a memory bus and connects to a graphics processor 1250 via an Accelerated Graphics Port (AGP). The NB/MCH 1225 also connects to the SB/ICH 1220 via an internal bus (e.g., a unified media interface or a direct media interface). The CPU 1230 may contain one or more processors and even may be implemented using one or more heterogeneous processor systems.

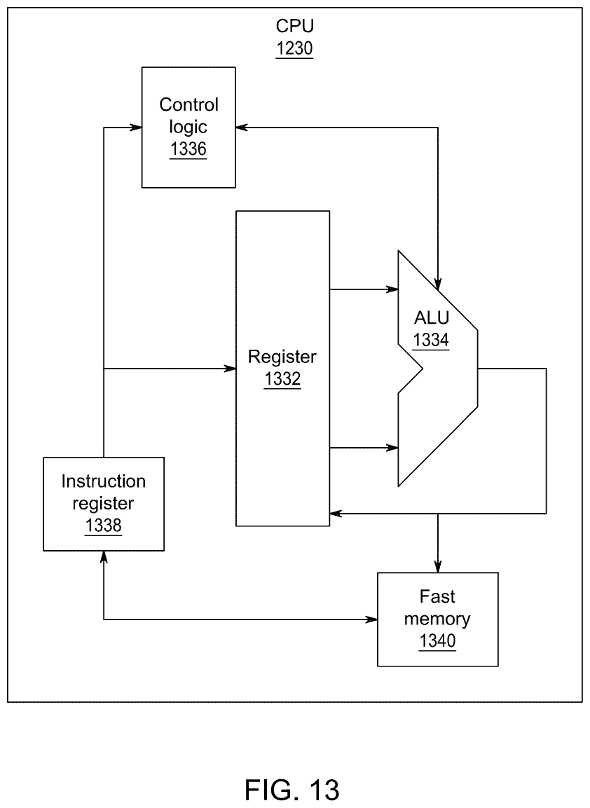

For example, FIG. 13 shows one implementation of the CPU 1230. In one implementation, an instruction register 1338 retrieves instructions from a fast memory 1340. At least part of these instructions is fetched from the instruction register 1338 by a control logic 1336 and interpreted according to the instruction set architecture of the CPU 1330. Part of the instructions can also be directed to a register 1332. In one implementation, the instructions are decoded according to a hardwired method, and in another implementation, the instructions are decoded according to a microprogram that translates instructions into sets of CPU configuration signals that are applied sequentially over multiple clock pulses. After fetching and decoding the instructions, the instructions are executed using an Arithmetic Logic Unit (ALU) 1334 that loads values from the register 1332 and performs logical and mathematical operations on the loaded values according to the instructions. The results from these operations can be feedback into the register 1332 and/or stored in the fast memory 1340. According to certain implementations, the instruction set architecture of the CPU 1230 can use a reduced instruction set architecture, a complex instruction set architecture, a vector processor architecture, a very large instruction word architecture. Furthermore, the CPU 1230 can be based on a Von Neuman model or a Harvard model. The CPU 1230 can be a digital signal processor, a Field-Programmable Gate Array (FPGA), an Application-Specific Integrated Circuit (ASIC), a Programmable Logic Array (PLA), a Programmable Logic Device (PLD), or a Complex Programmable Logic Device (CPLD). Further, the CPU 1230 can be an x86 processor by the Intel or by the AMD; an Advanced Reduced Instruction Set Computing (RISC) Machine (ARM) processor, a power architecture processor by, e.g., an International Business Machines Corporation (IBM); a Scalable Processor Architecture (SPARC) processor by Sun Microsystems or by Oracle; or other known CPU architecture.

Referring again to FIG. 12, the data processing system 1200 can include that the SB/ICH 1220 is coupled through a system bus to an I/O Bus, a ROM 1256, a Universal Serial Bus (USB) port 1264, a flash Binary Input/Output System (BIOS) 1268, and a graphics controller 1258. Peripheral Component Interconnect/Peripheral Component Interconnect Express (PCI/PCIe) devices can also be coupled to SB/ICH 888 through a PCI bus 1262.

The PCI devices may include, for example, Ethernet adapters, add-in cards, and Personal Computer (PC) cards for notebook computers. The HDD 1260 and an optical drive 1266 (e.g., CD-ROM) can use, for example, an Integrated Drive Electronics (IDE) or a Serial Advanced Technology Attachment (SATA) interface. In one implementation, an I/O bus can include a super I/O (SIO) device.

Further, the HDD 1260 and the optical drive 1266 can also be coupled to the SB/ICH 1220 through a system bus. In one implementation, a keyboard 1270, a mouse 1272, a serial port 1276, and a parallel port 1278 can be connected to the system bus through the I/O bus. Other peripherals and devices that can be connected to the SB/ICH 1220 using a mass storage controller such as the SATA or a Parallel Advanced Technology Attachment (PATA), an Ethernet port, an ISA bus, a Low Pin Count (LPC) bridge, a System Management (SM) bus, a Direct Memory Access (DMA) controller, and an Audio Compressor/Decompressor (Codec).

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry or based on the requirements of the intended back-up load to be powered.

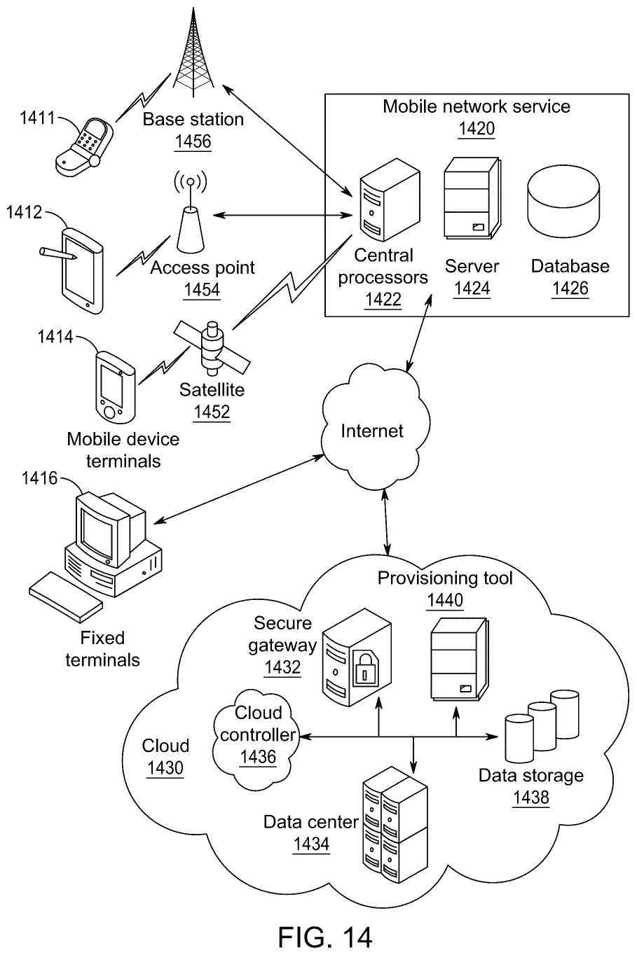

The functions and features described herein may also be executed by various distributed components of a system. For example, one or more processors may execute these system functions, wherein the processors are distributed across multiple components communicating in a network. The distributed components may include one or more client and server machines, which may share processing, as shown by FIG. 14, in addition to various human interface and communication devices (e.g., display monitors, smart phones, tablets, personal digital assistants (PDAs)). More specifically, FIG. 14 illustrates client devices including a smart phone 1411, a tablet 1412, a mobile device terminal 1414 and fixed terminals 1416. These client devices may be commutatively coupled with a mobile network service 1420 via a base station 1456, an access point 1454, a satellite 1452 or via an internet connection. The mobile network service 1420 may comprise central processors 1422, a server 1424 and a database 1426. The fixed terminals 1416 and the mobile network service 1420 may be commutatively coupled via an internet connection to functions in cloud 1430 that may comprise a security gateway 1432, a data center 1434, a cloud controller 1436, a data storage 1438 and a provisioning tool 1440. The network may be a private network, such as the LAN or the WAN, or may be the public network, such as the Internet. Input to the system may be received via direct user input and received remotely either in real-time or as a batch process. Additionally, some implementations may be performed on modules or hardware not identical to those described. Accordingly, other implementations are within the scope that may be disclosed.

The above-described hardware description is a non-limiting example of corresponding structure for performing the functionality described herein.

Numerous modifications and variations of the present disclosure are possible in light of the above teachings. It is therefore to be understood that the invention may be practiced otherwise than as specifically described herein.

1. A method of negating a hardware mismatch in a Radio Frequency (RF) front-end with an on-chip passive double edge-tuning mechanism, comprising:
generating a pair of Local Oscillator (LO) signals with a predefined 90° phase difference;
adjusting, using a passive delay tuning mechanism, a rising edge and a falling edge of one of the pair of LO signals to:
compensate for a gain mismatch, ε, between the pair of LO signals by symmetrically modifying a pulse width of a first LO signal of the pair of LO signals, and
compensate for a phase mismatch, θ, between the pair of LO signals by symmetrically delaying or advancing both rising and falling edges of the first LO signal; and
performing the adjusting directly in a RF domain at LO signal generation stage, prior to digitization by an Analog-to-Digital Converter (ADC) in a receiver front-end of the RF front-end, or after Digital-to-Analog Converter (DAC) in a transmitter front-end of the RF front-end.

2. The method of claim 1, wherein the adjusting reduces residual sideband (RSB) levels and error vector magnitude (EVM) without introducing additional power-hungry or computationally intensive circuitry.

3. The method of claim 1, wherein the gain mismatch, ε, is compensated by reducing the pulse width for the first LO signal to balance a relative amplitude difference between the pair of LO signals.

4. The method of claim 1, wherein the gain mismatch, ε, is compensated by:
reducing the pulse width of the first LO signal by a first predetermined value, G_{D}, wherein each of the rising edge and the falling edge of the first LO signal is reduced by a half of the first predetermined value, G_{D}/2.

5. The method of claim 4, wherein the first predetermined value, G_{D}, is determined as G_{D}=4ε/f_{LO}, where ε is an absolute gain mismatch of the RF front-end, and f_{LO} is an operation frequency of the RF front-end.

6. The method of claim 1, wherein the phase mismatch, θ, is compensated by shifting a phase of the first LO signal symmetrically for both positive and negative polarities to maintain a specified orthogonality between the pair of LO signals.

7. The method of claim 1, wherein the phase mismatch, θ, is compensated by shifting a phase of the first LO signal by a second predetermined value, P_{D}, without changing a phase shift of the first LO signal.

8. The method of claim 7, wherein the second predetermined value, P_{D}, is an absolute phase mismatch of the RF front-end.

9. The method of claim 1, wherein adjusting the rising edge and the falling edge includes:
adjusting the rising edge and the falling edge independently using edge-tunable inverters of the passive delay tuning mechanism.

10. The method of claim 1, wherein the pair of LO signals includes In-phase Local Oscillator (I-LO) signals and Quadrature Local Oscillator (Q-LO) signals.

11. The method of claim 1, wherein the first LO signal further comprises a positive LO pulse and a negative LO pulse.

12. An apparatus for negating a hardware mismatch in a Radio Frequency (RF) front-end, the apparatus comprising:
a Local Oscillator (LO) generator configured to generate a pair of LO signals with a predefined 90° phase difference;
a set of edge-tunable delay cells integrated within the LO generator, configured to passively modify a pulse width and a phase of the pair of LO signals to compensate for a gain mismatch, ε, or a phase mismatch, θ; and
a controller configured to provide calibration codes to the set of edge-tunable delay cells for adjusting gain and phase imbalances based on the gain mismatch, ε, and the phase mismatch, θ.

13. The apparatus of claim 12, wherein the set of edge-tunable delay cells is configured to:
modify the pulse width of a first LO signal of the pair of LO signals by reducing the pulse width of the first LO signal by a first predetermined value, G_{D}, wherein each of a rising edge and a falling edge of the first LO signal is reduced by a half of the first predetermined value, G_{D}/2.

14. The apparatus of claim 12, wherein the set of edge-tunable delay cells is configured to:
modify the phase of a first LO signal of the pair of LO signals by shifting the phase of the first LO signal symmetrically on both a rising edge and a falling edge of the first LO signal by a second predetermined value, P_{D}, ensuring that an adjusted phase difference between the pair of LO signals is P_{D}-θ.

15. The apparatus of claim 12, wherein the controller is configured to:
determine a gain adjustment and a phase adjustment based on the gain mismatch, ε, and the phase mismatch, θ, respectively, and
determine the calibration codes for achieving the gain adjustment and the phase adjustment.

16. The apparatus of claim 12, wherein the set of edge-tunable delay cells comprise:
inverter-based circuits with skew factors that allow for controlling a magnitude of the pulse width and a phase shift of a rising edge and a falling edge of a first LO signal of the pair of LO signals.

17. The apparatus of claim 16, wherein the controller is configured to:
provide the calibration codes to the inverter-based circuits with skew factors to adjust the pulse width and the phase shift of the first LO signal to compensate for the gain mismatch, ε, and the phase mismatch, θ.

18. The apparatus of claim 12, wherein a calibration code is a 5-bit code that allows control of delays of a rising edge or a falling edge of a first LO signal of the pair of LO signals in sub-picosecond resolution.

19. The apparatus of claim 12, wherein the set of edge-tunable delay cells comprise:
a first inverter-based circuit for adjusting a rising edge of a first LO signal of the pair of LO signals; and
a second inverter-based circuit for adjusting a falling edge of the first LO signal.

20. The apparatus of claim 12, wherein the gain mismatch, ε, or the phase mismatch, θ, is compensated in a RF domain before analog-to-digital conversion, reducing a signal-to-noise and distortion ratio (SNDR) requirements on subsequent analog-to-digital converters (ADCs) in a receiver front-end of the RF front-end.
